(19) United States
(12) Patent Application Publication
(10) Pub. No.: US 2026/0262412 A1
(43) Pub. Date: Sep. 3, 2026

(54) Display Apparatus

(71) Applicant: LG Display Co., Ltd., Seoul (KR)

(72) Inventor: Hyunsu Lee, Paju-si (KR)

(21) Appl. No.: 19/347,124

(22) Filed: Oct. 1, 2025

(30) Foreign Application Priority Data
Feb. 28, 2025 (KR) 10-2025-0026294

(51) Int. Cl. H10K 59/80; H05K 1/02; H10K 59/95

(52) U.S. Cl. CPC H10K 59/80; H05K 1/0277; H10K 59/95; H05K 2201/09027; H05K 2201/10128

(57) ABSTRACT

Embodiments of the present disclosure are directed to a display apparatus. The display apparatus includes a display panel in which a plurality of pixels is disposed, a printed circuit board attached to a perimeter of an end portion of the display panel, a first plate below the display panel, and a second plate below the first plate. The printed circuit board includes one or more through holes passing through the printed circuit board in a thickness direction of the printed circuit board, and a lower surface of the second plate is exposed in one or more areas where the one or more through holes are disposed.

### CROSS-REFERENCE TO RELATED APPLICATION

The present application claims priority to Republic of Korea Patent Application No. 10-2025-0026294, filed February 28, 2025, which is incorporated by reference in its entirety.

### BACKGROUND

### Field

The present disclosure relates to a display apparatus.

### Description of the Related Art

As the information society develops, various demands for display apparatuses for displaying images are increasing, and various types of display apparatuses, such as a liquid crystal display (LCD) apparatus and an organic light-emitting diode (OLED) display apparatus, are being utilized.

Generally, a display apparatus includes a display area in which images are displayed and a non-display area formed around the display area. In the display apparatus, the non-display area is also referred to as a bezel area, and consumer demand for a display apparatus with a minimized bezel area has been increasing recently.

In addition, the consumer demand for a display apparatus with a minimized thickness has been increased recently.

### SUMMARY

The present disclosure is directed to providing a display apparatus capable of suppressing or preventing a bubble issue that may occur in a printed circuit board.

The present disclosure is also directed to providing a display apparatus with a reduced thickness.

The present disclosure is also directed to providing a display apparatus with improved reliability by minimizing bubble defects on a printed circuit board.

Objects of the present disclosure are not limited to the above objects, and other technical objects may be inferred from the following embodiments.

According to one or more embodiments of the present disclosure, there is provided a display apparatus including a display panel in which a plurality of pixels are disposed, a printed circuit board attached to a perimeter of an end portion of the display panel, a first plate below the display panel, and a second plate below the first plate, in which the printed circuit board includes one or more through hole passing through the printed circuit board in a thickness direction of the printed circuit board, and a lower surface of the second plate is exposed in one or more areas where the one or more through holes are disposed.

Detailed matters of other embodiments are included in the detailed description and accompanying drawings.

According to one or more embodiments of the present disclosure, it is possible to suppress or prevent a bubble issue that may occur in the printed circuit board.

According to one or more embodiments of the present disclosure, it is possible to provide the display apparatus with a reduced thickness.

According to one or more embodiments of the present disclosure, it is possible to improve reliability by minimizing bubble defects on the printed circuit board.

According to one or more embodiments of the present disclosure, it is possible to improve the reliability of the display apparatus, thereby implementing the extended lifetime and low power of the display apparatus and also reducing power consumption.

However, effects obtainable from the present disclosure are not limited to the above effects, and other effects that are not described will be able to be clearly understood by those skilled in the art to which the present disclosure pertains based on the following description.

### BRIEF DESCRIPTION OF THE DRAWINGS

FIG. 1 is a configuration diagram of a display apparatus according to one or more embodiments of the present disclosure.

FIG. 2 is a plan view showing a display panel and a printed circuit board of the display apparatus according to FIG. 1.

FIG. 3 is a cross-sectional view showing a bent state of a display panel according to one or more embodiments of the present disclosure.

FIG. 4 is a cross-sectional view of one pixel of the display panel according to one or more embodiments of the present disclosure.

FIG. 5 is a rear view of the display apparatus with a bent display panel.

FIG. 6 is a cross-sectional view along line A-A’ in FIG. 5.

FIG. 7 is a rear view of the display apparatus according to one or more embodiments of the present disclosure.

FIG. 8 is a rear view of a display apparatus according to one or more embodiments of the present disclosure.

FIG. 9 is a cross-sectional view of a display apparatus according to one or more embodiments of the present disclosure.

### DETAILED DESCRIPTION

Hereinafter, embodiments will be described with reference to the accompanying drawings. In the specification, when a certain component (or a region, a layer, a portion, etc.) is described as “on,” “connected,” or “coupled to” another component, it means that the certain component may be directly connected/coupled to another component or still another component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes”, “comprises” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

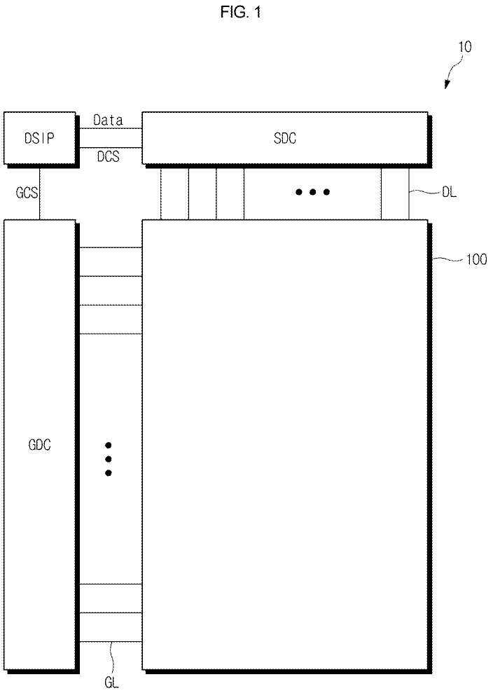

FIG. 1 is a configuration diagram of a display apparatus according to one or more embodiments of the present disclosure.

A display apparatus 10 according to one or more embodiments may perform an image display function and a touch sensing function (touch input function).

The display apparatus 10 according to one or more embodiments may include a display panel 100, a source driving circuit SDC, a gate driving circuit GDC, a display controller DSIP, etc. The embodiments of the present disclosure are not limited thereto.

The display panel 100 may include a plurality of pixels disposed in a display area of a base substrate, and driving units disposed in the non-display area around the display area to drive the pixels.

The pixels may include transistors connected to the driving units by control signal lines, and light-emitting elements connected to the transistors.

The transistors may be turned on or off according to control signals applied through the control signal lines to control the amount of a current applied to the light-emitting elements.

The light-emitting elements may emit light with a brightness corresponding to the amount of a current applied through the transistors. Although the light emitting element may include an organic light emitting diode, the embodiments of the present disclosure are not limited thereto. For example, the light emitting element may include an inorganic light emitting diode, a quantum dot diode, a micro-LED diode, a mini-LED diode, or the like, but the embodiments of the present disclosure are not limited thereto.

The display panel 100 may have a plurality of data lines DL and a plurality of gate lines GL. The display panel 100 may include a plurality of pixels. A plurality of pixels may display an image. The plurality of pixels may be arranged by being defined by the plurality of data lines DL and/or the plurality of gate lines GL.

A source driving circuit SDC may drive the plurality of data lines DL. A gate driving circuit GDC may drive the plurality of gate lines GL.

The display controller DSIP may control the source driving circuit SDC and the gate driving circuit GDC. The display controller DSIP may control the source driving circuit SDC and the gate driving circuit GDC by supplying various driving control signals DCS and GCS to the source driving circuit SDC and the gate driving circuit GDC.

The display controller DSIP may start scanning according to the timing implemented in each frame, convert externally input image data into a data signal format used in the data driving circuit SDC, output the converted image data Data, and control data driving at an appropriate time according to the scanning.

The display controller DSIP may receive various timing signals including, for example, a vertical synchronization signal, a horizontal synchronization signal, an input data enable signal, a clock signal, etc. from an external device (e.g., a host system) together with the input image data.

The display controller DSIP may not only convert the input image data input from the outside to suit the data signal format used in the source driving circuit SDC and output the converted image data, but also, to control the source driving circuit SDC and the gate driving circuit GDC to receive timing signals such as a vertical synchronization signal, a horizontal synchronization signal, an input data enable signal, or a clock signal, and generate and output various driving control signals DCS and GCS to the source driving circuit SDC and the gate driving circuit GDC.

The source driving circuit SDC may drive the plurality of data lines DL by receiving the image data Data from the display controller DSIP and supplying the data voltage to the plurality of data lines DL. The source driving circuit SDC may be a data driving circuit, but the embodiments of the present disclosure are not limited thereto.

The source driving circuit SDC may be implemented by including at least one source driver integrated circuit (SDIC), but the embodiments of the present disclosure are not limited thereto.

The gate driving circuit GDC may drive the plurality of gate lines GL by supplying a scan signal to the plurality of gate lines GL. The gate driving circuit GDC may be a scan driving circuit, but the embodiments of the present disclosure are not limited thereto.

The gate driving circuit GDC may be implemented by including at least one gate driver integrated circuit (GDIC), but the embodiments of the present disclosure are not limited thereto.

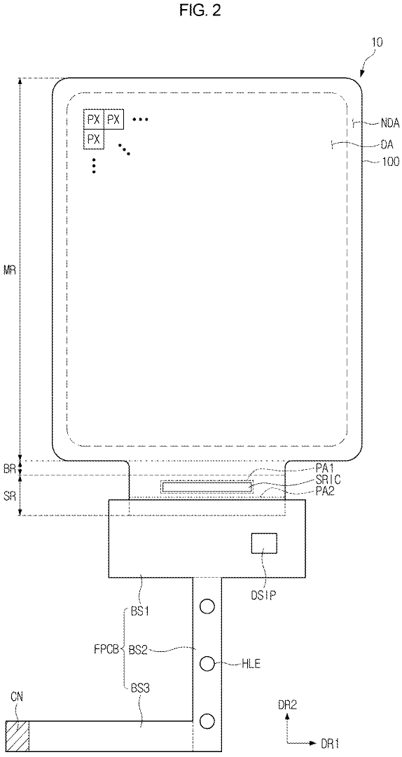

The display apparatus 10 according to one or more embodiments may include a touch panel, a touch driving circuit, a touch controller, and the like to provide a touch sensing function. The touch panel may be formed integrally with the display panel 100 but is not limited thereto. The touch panel may be formed separately on the display panel 100. The touch driving circuit may be integrated with the source driving circuit SDC and included in an integrated circuit (see SRIC in FIG. 2), but the embodiments of the present disclosure are not limited thereto.

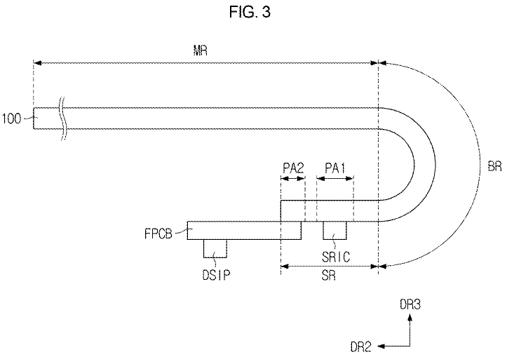

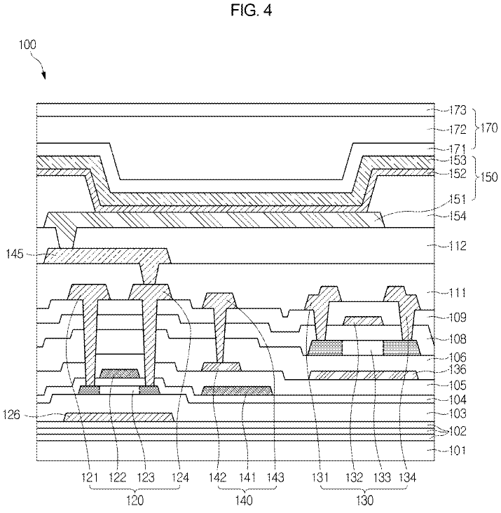

FIG. 2 is a plan view showing a display panel and a printed circuit board of the display apparatus according to FIG. 1. FIG. 3 is a cross-sectional view showing a bent state of a display panel according to one or more embodiments of the present disclosure. FIG. 4 is a cross-sectional view of one pixel of the display panel according to one or more embodiments of the present disclosure.

Referring to FIGS. 2 to 4, the display panel 100 may include a display area DA including a plurality of pixels PX and a non-display area NDA around the display area DA.

The display area DA may include short sides extending in the first direction DR1 and long sides extending in the second direction DR2. The non-display area NDA may surround the display area DA. The non-display area NDA may be located at one side in the first direction DR1, the other side in the first direction DR1, one side in the second direction DR2, and the other side in the second direction DR2 of the display area DA, but the embodiments of the present disclosure are not limited thereto.

The non-display area NDA located at the other side of the display area DA in the second direction DR2 may extend further from a central portion of the other side in the second direction DR2 toward the other side in the second direction DR2 of the display area DA. A width of the non-display area NDA in the first direction DR1 further extending from the central portion of the other side in the second direction DR2 toward the other side in the second direction DR2 of the display area DA may be smaller than a width of the non-display area NDA in the first direction DR1 adjacent to the other side of the display area DA in the second direction DR2.

The display panel 100 may include a first region MR, a second region SR, and a third region BR between the first region MR and the second region SR.

The display area DA and the non-display area NDA surrounding four surfaces of the display area DA may form the first region MR.

The portion extending further from the central portion of the other side of the display area DA in the second direction DR2 toward the other side of the second direction DR2 may form the third region BR and the second region SR. The second region SR may include a first pad area PA1 and a second pad area PA2 located at an end portion of the other side of the second region SR in the second direction DR2.

The third region BR may be disposed between the second region SR and the first region MR. The third region BR of the display panel 100 may be bent in a thickness direction (or a third direction DR3). Accordingly, the first region MR and the second region SR may overlap each other in the thickness direction. The display panel 100 may be bent in such a manner that a lower surface of the first region MR faces an upper surface of the second region SR.

For example, the first region MR may be a main region or a display region, but is not limited thereto. For example, the second region SR may be a sub-region, but is not limited thereto. For example, the third region BR may be a bending region or a variable region, but is not limited thereto.

The display apparatus 10 may further include an integrated circuit SRIC disposed in the first pad area PA1 and a printed circuit board FPCB attached to the second pad area PA2.

A plurality of pads connected to the integrated circuit SRIC and the printed circuit board FPCB may be disposed in each of the first pad area PA1 and the second pad area PA2. The integrated circuit SRIC may be formed, for example, in the form of a driving chip (IC), but is not limited thereto. In one or more embodiments, the integrated circuit SRIC is disposed in a chip-on-plastic manner and the integrated circuit SRIC is directly mounted on the display panel 100.

The printed circuit board FPCB may be attached to one end portion of the display panel 100 in the second direction DR2 and electrically connected to the display panel 100. Specifically, the printed circuit board FPCB may be attached to the second region SR of the display panel 100.

A controller may be disposed on the printed circuit board FPCB. The controller may include at least one controller. Only one controller may be disposed on the printed circuit board FPCB. For example, the controller may be the display controller DSIP, but the embodiments of the present disclosure are not limited thereto. When the controller is provided as a plurality of controllers, controllers other than the display controller DSIP may include a touch controller, but the embodiments of the present disclosure are not limited thereto.

The printed circuit board FPCB may further include a connector CN and may be electrically connected to a main circuit board, etc. through the connector CN, but the embodiments of the present disclosure are not limited thereto.

A thickness of the printed circuit board FPCB may range from 60 micrometers (1×10⁻⁶ meters) to 100 micrometers, range from 72 micrometers to 88 micrometers, or may be 80 micrometers.

The printed circuit board FPCB may include a first substrate portion BS1, a second substrate portion BS2, and a third substrate portion BS3.

The first substrate portion BS1 may be an area attached to the second region SR of the display panel 100. The first substrate portion BS1 may extend in the first direction DR1 and have a width in the second direction DR2 but is not limited thereto. At least one controller may be disposed on the first substrate portion BS1. For example, the controller may be the display controller DSIP, but the embodiments of the present disclosure are not limited thereto.

The second substrate portion BS2 may extend from the first substrate portion BS1 in the second direction DR2. The second substrate portion BS2 may protrude from the other end of the first substrate portion BS1 in the second direction DR2 and extend in the second direction DR2.

The printed circuit board FPCB may further include at least one through hole HLE. The through hole HLE may be defined by the printed circuit board FPCB. For example, the through hole HLE may be defined by the second substrate portion BS2 of the printed circuit board FPCB but is not limited thereto.

The second substrate portion BS2 may define at least one through hole HLE formed by passing through the second substrate portion BS2 in the thickness direction. The through hole HLE may be disposed on the second substrate portion BS2. The through hole HLE may be provided as a plurality of through holes. In FIG. 2, the through hole HLE may be provided as three through holes, but the embodiments of the present disclosure are not limited thereto. For example, one, two, or four or more through holes HLE may be provided.

When the through hole HLE is provided as a plurality of through holes, the plurality of through holes HLE may be repeatedly disposed in an extension direction of the second substrate portion BS2. When the through hole HLE is provided as a plurality of through holes, the plurality of through holes HLE may be repeatedly disposed in the second direction DR2.

The through hole HLE may be circular in a plan view, but is not limited thereto. For example, the through hole HLE may have a polygonal shape, such as a triangle, quadrangle, pentagon, or the like, or a round shape, such as an oval or the like, in a plan view.

The through hole HLE may not overlap electronic devices disposed on the printed circuit board FPCB. For example, the through holes HLE may not overlap a controller, an integrated circuit, etc. The through holes HLE may not overlap the integrated circuit SRIC and not overlap the display controller DSIP in the thickness direction.

Since the printed circuit board FPCB includes the through holes HLE, it is possible to suppress or prevent bubble defects that may occur in the printed circuit board FPCB.

In addition, since the through holes HLE do not overlap the electronic devices disposed on the printed circuit board FPCB, it is possible to more smoothly suppress or prevent bubble defects that may occur in the printed circuit board FPCB.

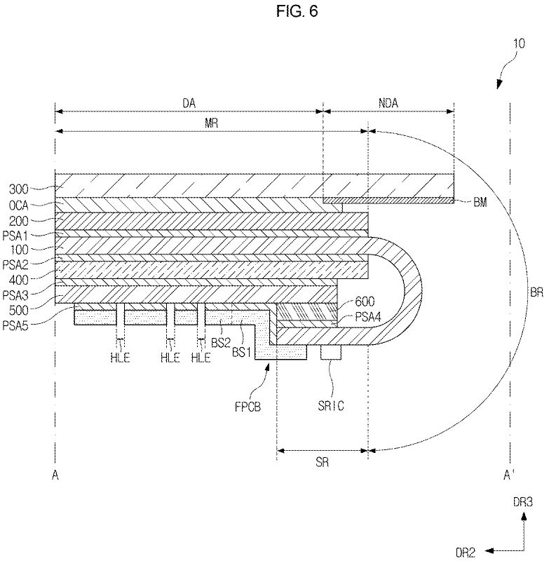

During the manufacturing process of the display apparatus 10, a liner may be attached to the printed circuit board FPCB. A process of bending the printed circuit board FPCB through the liner and bringing it into close contact with a second plate 500 (see FIG. 6) and a third plate 600 (see FIG. 6) may be performed.

After the printed circuit board FPCB is in close contact with the second plate 500 (see FIG. 6) and the third plate 600 (see FIG. 6), the liner may be removed. During the liner removal process, a force may be applied downward from the printed circuit board FPCB, resulting in bubble defects between the printed circuit board FPCB and the second plate 500 (see FIG. 6) and between the printed circuit board FPCB and the third plate 600 (see FIG. 6). As the thickness of the printed circuit board FPCB and the thickness of the fifth bonding layer PSA5 decrease, bubble defects can easily occur.

However, when the printed circuit board FPCB includes the through hole HLE, air and the like may pass through the through hole HLE, thereby preventing bubble formation, or, even when bubbles are formed, the air and the like may pass through the through hole HLE, thereby removing bubbles. Accordingly, since the printed circuit board FPCB includes the through hole HLE, it is possible to suppress or prevent bubble formation between the printed circuit board FPCB and the second plate 500 (see FIG. 6) and between the printed circuit board FPCB and the third plate 600 (see FIG. 6).

In addition, even when the thickness of the printed circuit board FPCB and the thickness of the fifth bonding layer PSA5 decrease, it is possible to smoothly suppress or prevent bubble defects through the through hole HLE.

In addition, heat generated from the display panel 100 and the like may be transferred to the second plate 500 and the like. In this case, as the through hole HLE exposes a lower surface of the second plate 500, the heat transferred from the display panel 100 can be more smoothly discharged to the outside.

Accordingly, the thickness of the display apparatus 10 can be reduced, and bubble defects and the like can be minimized, thereby improving the reliability of the display apparatus 10. Furthermore, the lifetime of the display apparatus 10 may be extended and low power may be implemented, thereby reducing power consumption.

The third substrate portion BS3 may protrude and extend from the other end of the second substrate portion BS2 in the second direction DR2 to the other side in the first direction DR1. The third substrate portion BS3 may be connected to the first substrate portion BS1 through the second substrate portion BS2. The second substrate portion BS2 may be disposed between the first substrate portion BS1 and the third substrate portion BS3.

A connector CN may be disposed on the third substrate portion BS3.

Hereinafter, a cross-sectional structure of one pixel PX disposed on the display panel 100 will be described.

The display panel 100 may include a base substrate 101, a first thin film transistor 120, a second thin film transistor 130, a light-emitting part 150, and an encapsulation part 170.

The base substrate 101 may include a flexible substrate. The base substrate 101 may include one or more plastic materials. Since the base substrate 101 of the display panel 100 includes a flexible substrate, the display apparatus 10 may be implemented as a foldable, stretchable, or bendable display apparatus, but the embodiments of the present disclosure are not limited thereto.

A buffer layer 102 may be disposed on the base substrate 101. The buffer layer 102 can minimize or delay the diffusion of moisture or oxygen penetrating the base substrate 101.

A first light-blocking layer 126 may be disposed on the buffer layer 102. The first light-blocking layer 126 can prevent light from transmitting a first semiconductor layer 123 of the first thin film transistor 120.

A first insulating layer 103 may be disposed on the first light-blocking layer 126.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, or the like, but is not limited thereto. The first semiconductor layer 123 may include a channel area, a source area, and a drain area.

The second insulating layer 104 may be disposed on the first semiconductor layer 123.

The first gate electrode 122 may be disposed on the second insulating layer 104. The first gate electrode 122 may be disposed on the second insulating layer 104 to overlap the channel area of the first semiconductor layer 123.

A third insulating layer 105 may be disposed on the first gate electrode 122.

The first source electrode 121 and the first drain electrode 124 may be disposed on the third insulating layer 105.

The first source electrode 121 and the first drain electrode 124 may be electrically connected to the first semiconductor layer 123 through contact holes.

A storage electrode 140 may be disposed to be spaced apart from the first thin film transistor 120. The storage electrode 140 may include a first storage electrode 141, a second storage electrode 142, and a third storage electrode 143.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-blocking layer 136 may be disposed on the same layer as the second storage electrode 142.

A fourth insulating layer 106 may be disposed on the second light-blocking layer 136.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

A fifth insulating layer 108 may be disposed on the second semiconductor layer 133.

The second gate electrode 132 may be disposed on the fifth insulating layer 108.

A sixth insulating layer 109 may be disposed on the second gate electrode 132.

The first source electrode 121, the first drain electrode 124, the third storage electrode 143, the second source electrode 131, and the second drain electrode 134 may be disposed on the sixth insulating layer 109.

The first thin film transistor 120 may be a driving transistor, and the second thin film transistor 130 may be a switching transistor, but the embodiments of the present disclosure are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material.

A second protective layer 112 may be disposed on the first protective layer 111. The second protective layer 112 may be formed of the same material as the first protective layer 111, but the embodiments of the present disclosure are not limited thereto.

A connection electrode 145 may be disposed between the first protective layer 111 and the second protective layer 112. The connection electrode 145 may electrically connect the first thin film transistor 120 to the light-emitting part 150.

The light-emitting part 150 may be disposed on the second protective layer 112. The light-emitting part 150 may include an anode electrode 151, an organic layer 152, and a cathode electrode 153.

The anode electrode 151 may be disposed on the second protective layer 112. The anode electrode 151 may be electrically connected to the first thin film transistor 120 through a contact hole formed in the second protective layer 112. The anode electrode 151 may be a reflective electrode that reflects light, but the embodiments of the present disclosure are not limited thereto.

The organic layer 152 may be disposed on the anode electrode 151. The organic layer 152 may include one or more light-emitting structures (or light-emitting elements or devices) stacked on the anode electrode 151 in the order or reverse order of a hole transfer layer and an electron transfer layer.

The organic layer 152 may be an organic light-emitting layer, an inorganic light-emitting layer, a quantum dot light-emitting layer, a micro light-emitting diode, a micro mini light-emitting diode, etc., but the embodiments of the present disclosure area not limited thereto.

The cathode electrode 153 may be disposed on the organic layer 152. The cathode electrode 153 may be a transparent electrode that transmits light, but the embodiments of the present disclosure are not limited thereto.

A bank 154 may be disposed to expose the anode electrode 151. The bank 154 may define an opening (or a light-emitting area EA) of the pixel PX and may be disposed to cover an edge of the anode electrode 151.

When the bank 154 is formed of a material containing black pigment, black dye, or the like, the bank 154 may be a black bank. In this case, it is possible to block external light or light reflected from the outside, thereby further improving brightness of the display apparatus.

A spacer may be further disposed on the bank 154.

The encapsulation part 170 may be disposed on the bank 154 or the light-emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material, but the embodiments of the present disclosure are not limited thereto.

Although not shown, a touch part capable of detecting a user’s touch may be further disposed on the encapsulation part 170.

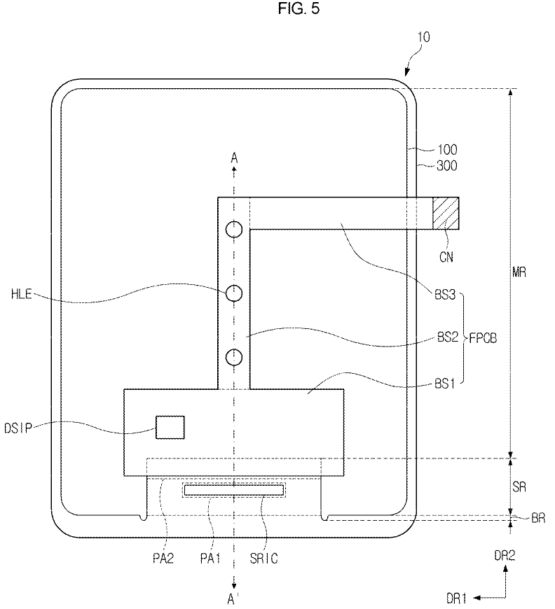

FIG. 5 is a rear view of the display apparatus with a bent display panel. FIG. 6 is a cross-sectional view along line A-A’ in FIG. 5.

FIG. 5 shows a rear view of the display apparatus 10 as viewed from the rear after the display panel 100 is bent as in FIG. 3.

Referring to FIGS. 5 and 6, the display apparatus 10 may include a plurality of stacked members. The display apparatus 10 may further include a polarizing layer 200 disposed on an upper surface of the display panel 100, a cover layer 300 disposed on an upper surface of the polarizing layer 200, a first plate 400 disposed on a lower surface (rear surface) of the display panel 100, and a second plate 500 disposed on a lower surface of the first plate.

However, the embodiments of the present disclosure are not limited thereto, and although not shown, the display apparatus 10 may further include a metal frame disposed below the second plate 500, a system frame capable of storing the stacked members, etc.

The display apparatus 10 may further include bonding layers disposed between stacked members. Specifically, the display apparatus 10 may further include the bonding layers disposed between the display panel 100, the polarizing layer 200, the cover layer 300, the first plate 400, and the second plate 500 to fixedly bond the components. The bonding layers may include the optical adhesive layer OCA, a first bonding layer PSA1, a second bonding layer PSA2, and a third bonding layer PSA3.

The optical adhesive layer OCA may be disposed between the polarizing layer 200 and the cover layer 300. The optical adhesive layer OCA may fixedly adhere the polarizing layer 200 and the cover layer 300.

The optical adhesive layer OCA may include a transparent adhesive. For example, the transparent adhesive may be an optically clear adhesive or an optically clear resin, but the embodiments of the present disclosure are not limited thereto.

The first bonding layer PSA1 may be disposed between the display panel 100 and the polarizing layer 200. The first bonding layer PSA1 may fixedly adhere the display panel 100 and the polarizing layer 200.

The second bonding layer PSA2 may be disposed between the first plate 400 and the display panel 100. The second bonding layer PSA2 may fixedly adhere the first plate 400 and the display panel 100.

The third bonding layer PSA3 may be disposed between the first plate 400 and the second plate 500. The third bonding layer PSA3 may fixedly adhere the first plate 400 and the second plate 500.

Each of the first bonding layer PSA1, the second bonding layer PSA2, and the third bonding layer PSA3 may include an adhesive or a transparent adhesive, but the embodiments of the present disclosure are not limited thereto. For example, the transparent adhesive may be an optically clear adhesive, an optically clear resin, or a pressure sensitive adhesive, but the embodiments of the present disclosure are not limited thereto.

The polarizing layer 200 may be disposed on the display panel 100. The polarizing layer 200 may polarize light emitted from the display panel 100 at a polarization angle. The polarizing layer 200 may emit light polarized at the polarization angle to the outside. The polarizing layer 200 may have a function of blocking reflection of light not including the light polarized at the polarization angle among external light.

The polarizing layer 200 may include a first phase retardation layer, a second phase retardation layer on the first phase retardation layer, and a polarizing layer on the second phase retardation layer, but the embodiments of the present disclosure are not limited thereto. FIG. 3 shows an example in which the polarizing layer 200 and the display panel 100 are separated, but the embodiments of the present disclosure are not limited thereto, and the polarizing layer 200 may be included in the display panel 100.

The cover layer 300 may be disposed on the polarizing layer 200. The cover layer 300 can protect members (e.g., the display panel 100 and the like) disposed below the cover layer 300 from the outside.

The cover layer 300 may be formed of a glass material including glass or quartz, but the embodiments of the present disclosure are not limited thereto. The cover layer 300 may be a cover layer formed by chemical reinforcement, but the embodiments of the present disclosure are not limited thereto. The cover layer 300 may be a cover window, a window cover, or a cover member, but the embodiments of the present disclosure are not limited thereto.

The cover layer 300 may be formed of a glass material, and in this case, the cover layer 300 can be damaged by an external force, resulting in glass fragments. To prevent the shattering of the glass fragments due to the damage to the cover layer 300 or to increase the durability of the cover layer 300, the display apparatus 10 may further include at least one additional layer on the cover layer 300.

The display apparatus 10 may further include a black matrix BM. The black matrix BM may define the non-display area NDA of the display apparatus 10. That is, the black matrix BM may be disposed in the non-display area NDA. The black matrix BM may block light from leaking to the non-display area NDA.

The black matrix BM may be disposed on a lower surface (rear surface) of the cover layer 300. The black matrix BM may be disposed to protrude from the cover layer 300 toward an optical adhesive layer OCA. A step may be caused by the black matrix BM, but the step can be eliminated by the optical adhesive layer OCA. In this case, the black matrix BM may be disposed between the cover layer 300 and the optical adhesive layer OCA.

The black matrix BM may be formed of a photosensitive organic material with a black pigment added thereto, but the embodiments of the present disclosure are not limited thereto. The black pigment may include carbon black, titanium oxide, or the like, but the embodiments of the present disclosure are not limited thereto.

The first plate 400 may be disposed below the display panel 100. The first plate 400 may be disposed below the display panel 100 to support the display panel 100. The first plate 400 may have a strength and thickness greater than or equal to a predetermined level or more to supplement the rigidity of the display panel 100. The first plate 400 can suppress wrinkles occurring on the display panel 100. The first plate 400 is disposed on the first region MR.

The first plate 400 may include a material capable of supporting the display panel 100. For example, the first plate 400 may include polyethylene terephthalate (PET), polyimide (PI), or polycarbonate (PC), but the embodiments of the present disclosure are not limited thereto.

The second plate 500 may be disposed below the first plate 400. The second plate 500 may be formed of a single layer, but is not limited thereto, and may also be formed of a plurality of layers.

The second plate 500 may include metal. However, the embodiments of the present disclosure are not limited thereto, and for example, the second plate 500 may include one or more materials selected from the group consisting of stainless steel (SUS), glass, ceramic, and metal, or a combination thereof, but the embodiments of the present disclosure are not limited thereto.

The display apparatus 10 may further include a third plate 600. The third plate 600 may be disposed on the second region SR of the display panel 100. The third plate 600 may be disposed between a part of the bent display panel 100 in the first region MR and a part of the bent display panel 100 in the second region SR. The third plate 600 may be disposed below the second plate 500 to face the second plate 500.

A fourth bonding layer PSA4 may be disposed between the part of the display panel 100 in the second region SR and the third plate 600. The display panel 100 and the third plate 600 may be fixedly adhered through the fourth bonding layer PSA4. The fourth bonding layer PSA4 may include an adhesive, a transparent adhesive, a pressure-sensitive adhesive, etc.

The third plate 600 may be formed of the same material as the first plate 400. The third plate 600 can protect the second region SR of the display panel 100.

The printed circuit board FPCB may overlap the first region MR. The printed circuit board FPCB may be disposed or attached to the second plate 500 on the first region MR. A fifth bonding layer PSA5 may be disposed between the printed circuit board FPCB and the second plate 500 of the first region MR.

The display controller DSIP may be disposed at one side of the printed circuit board FPCB. One surface of the printed circuit board FPCB may be a surface opposite to the other surface attached to the second plate 500.

The display panel 100 may include the third region BR, and the display panel 100 may be bent in the third region BR. Accordingly, a bezel area of the display panel 100 can be reduced.

The printed circuit board FPCB may be attached to an end portion of the bent display panel 100. The printed circuit board FPCB may extend along the end portion and a side surface of the second region SR of the display panel 100, a side surface of the third plate 600, and a lower surface of the second plate 500. The printed circuit board FPCB may be fixedly attached to the second plate 500 through the fifth bonding layer PSA5.

A thickness of the fifth bonding layer PSA5 may range from 20 micrometers (1×10⁻⁶ meters) to 30 micrometers, range from 22 micrometers to 28 micrometers, or may be 25 micrometers.

The first substrate portion BS1 may extend along upper and side surfaces around the end portion of the second region SR of the display panel 100, a side surface of the third plate 600, and a lower surface of the second plate 500.

The first substrate portion BS1 may be fixedly adhered to the side surface of the display panel 100, the side surface of the third plate 600, and the lower surface of the second plate 500 through the fifth bonding layer PSA5 but is not limited thereto.

The second substrate portion BS2 may extend along the second plate 500. The second substrate portion BS2 may be fixedly attached to the lower surface of the second plate 500 through the fifth bonding layer PSA5.

The fifth bonding layer PSA5 may be omitted in areas where the through holes HLE are located. That is, the fifth bonding layer PSA5 may be located outside the through hole HLE.

Accordingly, the lower surface of the second plate 500 may be exposed in the areas where the through holes HLE are disposed. Since the fifth bonding layer PSA5 is omitted in the areas where the through holes HLE are located, bubble defects can be more effectively suppressed or prevented.

Accordingly, the thickness of the display apparatus 10 can be reduced, and the movement of the printed circuit board FPCB can be minimized. Furthermore, it is possible to minimize physical interference between the printed circuit board FPCB and set components, reinforce durability of the display apparatus, and extend the lifetime of the display apparatus.

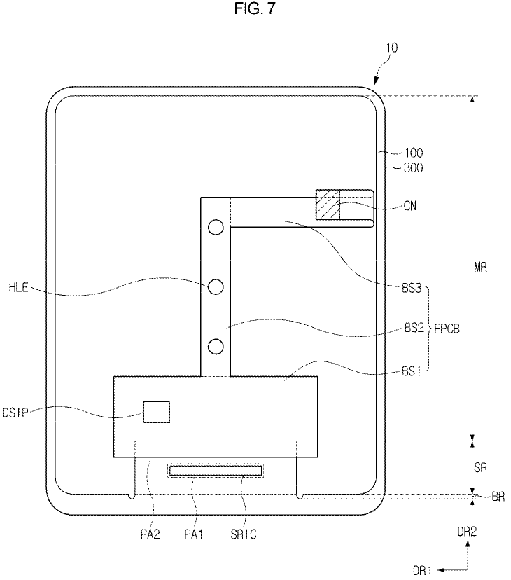

FIG. 7 is a rear view of the display apparatus according to one or more embodiments of the present disclosure.

Referring to FIGS. 6 and 7, when the display apparatus 10 is stored in a housing or the like, a portion of the printed circuit board FPCB may be bent.

Specifically, as shown in FIG. 6, the third substrate portion BS3 of the printed circuit board FPCB may protrude outward farther than the cover layer 300 in the first direction DR1. The third substrate portion BS3 of the printed circuit board FPCB protruding outward farther than the cover layer 300 may be bent downward in the third direction DR3 and disposed to overlap the cover layer 300 in the thickness direction (third direction DR3).

By bending the third substrate portion BS3 of the printed circuit board FPCB protruding outward farther than the cover layer 300 and disposed to overlap the cover layer 300, the display apparatus 10 can be prevented from colliding with the housing or the like during the process of being stored in the housing or the like, and the display apparatus 10 can be stored more smoothly in the housing or the like.

Hereinafter, other embodiments of the present disclosure will be described. For contents that are substantially the same as those described with reference to FIGS. 1 to 7 among components included in other embodiments, the same reference numerals are given, and overlapping contents may be omitted or briefly described.

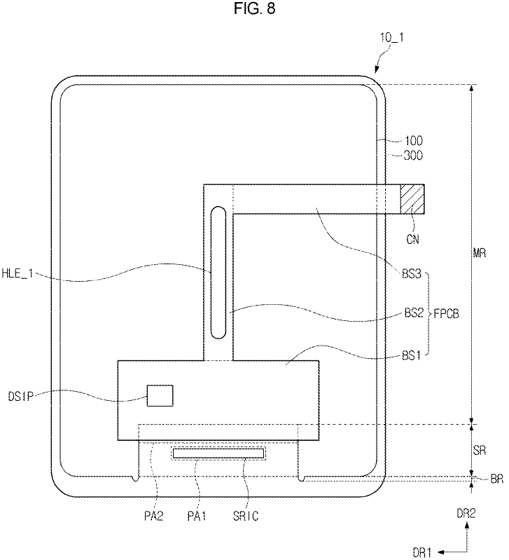

FIG. 8 is a rear view of a display apparatus according to one or more embodiments of the present disclosure.

Referring to FIG. 8, a display apparatus 10_1 according to one or more embodiments includes the printed circuit board FPCB, and the printed circuit board FPCB may include one through hole HLE_1. The through hole HLE_1 may be disposed on the second substrate portion BS2 and may extend in a direction in which the second substrate portion BS2 extends.

That is, the second substrate portion BS2 may extend in the second direction DR2, and the through hole HLE_1 may also extend in the second direction DR2 and may be formed in a shape having a length in the second direction DR2. A length of the through hole HLE_1 in the second direction DR2 may be larger than a width thereof in the first direction DR1.

Even in this case, since the printed circuit board FPCB includes the through hole HLE_1, it is possible to suppress or prevent bubble defects that may occur in the printed circuit board FPCB.

Furthermore, since the through hole HLE_1 extends in the direction in which the second substrate portion BS2 extends, the size of the through hole HLE_1 may increase, making the process of forming the through hole HLE_1 easier.

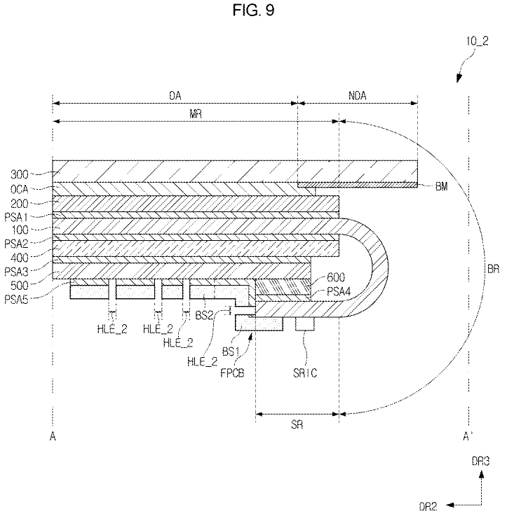

FIG. 9 is a cross-sectional view of a display apparatus according to one or more embodiments of the present disclosure.

Referring to FIG. 9, a display apparatus 10_2 according to one or more embodiments includes the printed circuit board FPCB, and a plurality of through holes HLE_2 formed in the printed circuit board FPCB may be disposed in the first substrate portion BS1 and the second substrate portion BS2. In areas where the through holes HLE_2 are disposed, the fifth bonding layer PSA5 may not be disposed.

In the areas where the through holes HLE_2 are disposed, the lower surface of the second plate 500 may be exposed. In addition, a side surface of the display panel 100 may be exposed in areas overlapping at least one of the through holes HLE_2. However, the embodiments of the present disclosure are not limited thereto, and the side surface of the third plate 600 may also be exposed in the areas overlapping at least one of the through holes HLE_2.

Even in this case, since the printed circuit board FPCB includes the through holes HLE_2, it is possible to suppress or prevent bubble defects that may occur in the printed circuit board FPCB.

A display apparatus according to various embodiments of the present disclosure may be described as follows.

According to one or more embodiments of the present disclosure, there is provided a display apparatus including a display panel in which a plurality of pixels are disposed, a printed circuit board attached to a perimeter of an end portion of the display panel, a first plate below the display panel, and a second plate below the first plate, in which the printed circuit board includes one or more through hole passing through the printed circuit board in a thickness direction of the printed circuit board, and a lower surface of the second plate is exposed in one or more areas where the one or more through holes are disposed.

According to one or more embodiments of the present disclosure, the printed circuit board may include a first substrate portion attached to the display panel and extending in a first direction, and a second substrate portion protruding from the first substrate portion and extending in a second direction intersecting the first direction, and the through hole may be disposed in the second substrate portion.

According to one or more embodiments of the present disclosure, the through hole may be provided as a plurality of through holes, and the plurality of through holes may be repeatedly disposed in the second direction.

According to one or more embodiments of the present disclosure, the printed circuit board may further include a third substrate portion which protrudes from the second substrate portion and extends in the first direction and on which a connector is disposed, and the second substrate portion may be disposed between the first substrate portion and the third substrate portion.

According to one or more embodiments of the present disclosure, at least a portion of the printed circuit board may be attached on the lower surface of the second plate.

According to one or more embodiments of the present disclosure, the display apparatus may further include fifth bonding layer disposed between the printed circuit board and the second plate, wherein there is no fifth bonding layer in an area where the through hole is located.

According to one or more embodiments of the present disclosure, the display apparatus may further include a third plate disposed below the display panel, in which the display panel may include a first region in which a plurality of pixels are disposed, a second region overlapping the first region in a thickness direction, and a third region disposed between the first region and the second region and bent in the thickness direction, the first plate may be disposed on the first region, and the third plate may be disposed on the second region and between a part of the display panel in the first region and a part of the display panel in the second region.

According to one or more embodiments of the present disclosure, the printed circuit board may be attached while extending from a lower surface of the part of the display panel in the second region in a direction faces away from the second plate along a side surface of the display panel, a side surface of the third plate, and the lower surface of the second plate.

According to one or more embodiments of the present disclosure, the display apparatus may further include a controller mounted on the printed circuit board, in which the controller may be disposed not overlapped with the through hole.

According to one or more embodiments of the present disclosure, the display apparatus may further include a polarizing layer disposed on the display panel, an optical adhesive layer disposed on the polarizing layer, and a cover layer disposed on the optical adhesive layer.

According to one or more embodiments of the present disclosure, wherein the display apparatus may further comprise a cover layer on the display panel, a part of the third substrate portion protruding outward farther than the cover layer in the first direction is bent and overlapped with the cover layer in the thickness direction.

According to one or more embodiments of the present disclosure, wherein a length of the through hole in the second direction may be larger than a width of the through hole in the first direction.

According to one or more embodiments of the present disclosure, the printed circuit board may include: a first substrate portion attached to the display panel and extending in a first direction; and a second substrate portion protruding from the first substrate portion and extending in a second direction intersecting the first direction, and wherein the through hole is provided as a plurality of through holes, the through holes are disposed in the first substrate portion and the second substrate portion.

Although the embodiments have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

What is claimed is:

1. A display apparatus, comprising:
a display panel in which a plurality of pixels are disposed;
a printed circuit board attached to a perimeter of an end portion of the display panel;
a first plate below the display panel; and
a second plate below the first plate,
wherein the printed circuit board includes one or more through holes passing through the printed circuit board in a thickness direction of the printed circuit board, and
a lower surface of the second plate is exposed in one or more areas where the one or more through holes are disposed.

2. The display apparatus of claim 1, wherein the printed circuit board includes:
a first substrate portion attached to the display panel and extending in a first direction; and
a second substrate portion protruding from the first substrate portion and extending in a second direction intersecting the first direction, and
wherein a through hole of the one or more through holes is disposed in the second substrate portion.

3. The display apparatus of claim 2, wherein the one or more through holes include a plurality of through holes, and the plurality of through holes are repeatedly disposed in the second direction.

4. The display apparatus of claim 3, wherein the printed circuit board further includes a third substrate portion that protrudes from the second substrate portion and extends in the first direction,
wherein a connector is disposed on the third substrate portion, and
wherein the second substrate portion is disposed between the first substrate portion and the third substrate portion.

5. The display apparatus of claim 1, wherein at least a portion of the printed circuit board is attached to the lower surface of the second plate.

6. The display apparatus of claim 5, further comprising a bonding layer disposed between the printed circuit board and the second plate,
wherein the bonding layer is not in an area where a through hole of the one or more through holes is located.

7. The display apparatus of claim 1, further comprising a third plate below the display panel,
wherein the display panel includes a first region in which a plurality of pixels are disposed, a second region overlapping the first region in a thickness direction, and a third region disposed between the first region and the second region and bent in the thickness direction,
wherein the first plate is disposed on the first region, and
wherein the third plate is disposed on the second region and between a part of the display panel in the first region and a part of the display panel in the second region.

8. The display apparatus of claim 7, wherein the printed circuit board is attached while extending from a lower surface of the part of the display panel in the second region in a direction facing away from the second plate along a side surface of the display panel, a side surface of the third plate, and the lower surface of the second plate.

9. The display apparatus of claim 1, further comprising a controller mounted on the printed circuit board,
wherein the controller is disposed not to overlap with a through hole of the one or more through holes.

10. The display apparatus of claim 1, further comprising a polarizing layer on the display panel, an optical adhesive layer on the polarizing layer, and a cover layer on the optical adhesive layer.

11. The display apparatus of claim 4, further comprising a cover layer on the display panel, a part of the third substrate portion protruding outward further than the cover layer in the first direction is bent and overlapped with the cover layer in the thickness direction.

12. The display apparatus of claim 2, wherein a length of the through hole in the second direction is larger than a width of the through hole in the first direction.

13. The display apparatus of claim 1, wherein the printed circuit board includes:
a first substrate portion attached to the display panel and extending in a first direction; and
a second substrate portion protruding from the first substrate portion and extending in a second direction intersecting the first direction,
wherein the one or more through holes include a plurality of through holes, and
wherein the plurality of through holes are disposed in the first substrate portion and the second substrate portion.
